(19) United States
(12) Patent Application Publication
(10) Pub. No.: US 2010/0081280 A1
(43) Pub. Date: Apr. 1, 2010

(54) METHOD OF PRODUCING A MIXED SUBSTRATE

(75) Inventors: Hubert Moriceau, St. Egreve (FR); Sylvie Satori, Meylan (FR); Anne-Marie Charvet, Vif (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: COMMISSARIAT A L'ENERGIE ATOMIQUE, Paris (FR)

(21) Appl. No.: 12/515,021

(22) PCT Filed: Nov. 28, 2007
(86) PCT No.: PCT/EP2007/062959

§ 371 Date: May 15, 2009

(30) Foreign Application Priority Data
Nov. 29, 2006 (FR) 06 55193

(51) Int. Cl. H01L 21/306

(52) U.S. Cl. 438/692; 257/E21.23

(57) ABSTRACT

The invention concerns a method of producing a mixed substrate, that is to say a substrate comprising at least one block of material different from the material of the substrate, the method comprising the following successive steps:
formation of a cavity in a substrate of first material, and from one of its faces, the formation of the cavity being carried out so as to leave at least part of the first material projecting from the bottom of the cavity,
formation of the block by means of a reaction, initiated from the walls of the cavity, between the first material and at least one chemical element contributed in order to obtain a second material filling the cavity, the formation of the block being carried out so as to obtain, from the part of the first material projecting, a protrusion of second material projecting on said face of the substrate.

### TECHNICAL FIELD

The invention relates to a method of producing a mixed substrate intended for manufacturing specific stacked structures. Such a stacked structure is obtained by bonding the mixed substrate with another substrate or a layer on a bonding interface.

### PRIOR ART

It is often necessary, in the semiconductor field, to manufacture structures by stacking and bonding. For example, two substrates may be assembled by molecular bonding (or “wafer bonding”) of a main face of one of the substrates with a main face of the other substrate. For this purpose, the faces to be put in contact must be carefully prepared to allow this molecular bonding. This preparation may involve chemical-mechanical polishing of the faces to be put in contact, cleaning of these faces and activation thereof in order to obtain close contact (faces of mirror quality).

This molecular bonding technique procures very good results for the bonding of semiconductor substrates having faces that are homogeneous with regard to their composition. However, the application of this technique to substrates having a non-homogeneous face may pose a problem. Such substrates are called “mixed substrates”. Thus the main face of a mixed substrate (the face to be bonded) may have at least one area of a different nature to the rest of the substrate. An example of a mixed substrate consists of a silicon substrate having blocks of silicon oxide lying flush on the face to be bonded of the substrate, the blocks of oxide alternating with silicon areas. Another example of a mixed substrate consists of a silicon substrate whose face to be bonded has an alternation of thin blocks of oxide and thick blocks of oxide. Yet another example of a mixed substrate consists of a semiconductor substrate whose face to be bonded has an alternation of electrically conductive areas and electrically insulating areas obtained by localised doping and/or inclusion of material that is conductive to a greater or lesser extent.

The surface preparation of a mixed substrate with a view to its molecular bonding may pose a problem. By way of example, the case of a silicon substrate will be examined, one face of which has at least one flush block of silicon oxide. The production of such a substrate will be described in relation to FIGS. 1A and 1B. FIG. 1A shows a substrate 1 made from silicon, one of the main faces of which has been etched to create a cavity 2 (only one cavity has been shown, but the substrate may include several). The main face of the substrate 1 is covered, outside the cavity, with a film 3 of silicon nitride serving as a mask. Advantageously, the film 3 of silicon nitride was deposited on the substrate 1 before the cavity was produced. It may even have served as a mask for producing said cavity. Silicon oxide is then caused to grow, by thermal oxidation, until the cavity is filled in. FIG. 1B shows the result obtained: a block of silicon oxide 4 in the silicon substrate 1. The method used also causes the formation of protuberances 5 at the edge of the cavity. These protuberances are due to the growth of the oxide from the top area 6 of the cavity 2 and the expansion of the thermal oxide with respect to the silicon. The oxide fills the cavity and extends beyond the initial bottom of the cavity.

FIG. 1B also shows the presence of silicon oxide on the nitride film 3. This is due to the oxidation process, which causes the partial consumption of the silicon nitride during the reaction.

The mixed substrate illustrated by FIG. 1B therefore requires surface preparation (by chemical-mechanical polishing or planarization) in order to be able to bond, by molecular adhesion, the face of the mixed substrate to a face of another substrate. This is because, in order to obtain good direct bonding, it is necessary to eliminate, to the maximum possible extent, any roughness and topology present on the surface.

One problem often encountered is that of a different efficacy of this planarization on the surfaces treated: this difference in efficacy depends for example on the distribution of the topologies on the surface or for example also to the nature of the different materials of the surface (selectivity of attack during mechanochemical planing).

It will then be noted that some areas are polished in excess compared with other areas (the so-called dishing phenomena). This results in slight depressions on the surface. It will be understood that these depressions are detrimental to close contact with a flat face of another substrate and that they give rise to bonding defects. In addition, after assembly of the two substrates, if these depressions appear on electrically insulating areas of one of the substrates, the result may be a degradation of the dielectric integrity of the insulating areas.

The applications sought with such bonded structures assume the production of insulating areas of several mm², or even several cm². These insulating areas are generated in blocks of suitable dimensions. Concerning the quality of the insulators, the dielectric stiffness must be good along an axis perpendicular to the surface of the substrate used. In the case of silicon dioxide insulating areas, in order to ensure good dielectric stiffness, it is preferable to produce this insulator by thermal oxidation. The thickness of silicon dioxide generated in a cavity is around twice the initial depth of the cavity produced in the silicon substrate.

Where it is wished for insulating areas of large size (several mm², or even several cm²), attempts at topology planing are a failure since a surface hollowing is caused between the protrusions because of the large dimensions of the blocks to be obtained. The result is flatness defects caused that prevent subsequent bonding, even if the surface roughness over dimensions of around a micrometre is satisfactory.

The U.S. Pat. No. 5,747,377 discloses a method of forming shallow insulating trenches on a face of a silicon substrate. To form field oxide regions, it is proposed to produce series of trenches in the substrate. The trenches corresponding to one and the same future region are separated by a wall, the width of which is of the same order of magnitude as the trenches. Next the oxidation of the walls (lateral oxidation) is proceeded with a view to filling in the trenches. In this case, the oxidation time is much lower than if the starting point was a simple cavity without walls. However, the electrical insulation may be defective vertically. In addition, the method disclosed by the U.S. Pat. No. 5,747,377 is intended particularly for producing field oxide regions for CMOS transistors. It involves a wall density that is too great to allow planarization with a small removal of material. The roughness of the insulating areas created from the trenches can be treated over micrometric dimensions but not on millimetric scales.

### DISCLOSURE OF THE INVENTION

The present invention was designed with a view to remedying the drawbacks of the prior art cited above.

The present invention proposes a method of producing a mixed substrate in which the cavities are formed with regularly spaced projections, greatly reducing the surface roughness. The density and lateral dimensions of the projection are limited so as to be able to effectively plane all the projections by removing a minimum of surface material on the structured substrate. The distance separating the projections may be around a hundred micrometres and the width of the projections may be around 0.1 to 6 μm.

The subject matter of the invention is a method of producing a mixed substrate, that is to say a substrate comprising at least one block of material different from the material of the substrate, the method comprising the following successive steps:
formation of a cavity in a substrate of first material, and from one of its faces,
formation of the block by means of a reaction, initiated from the walls of the cavity, between the first material and at least one chemical element contributed in order to obtain a second material filling the cavity,
planarizing first face of the substrate, characterised in that:
the step of forming the cavity is carried out so as to leave at least part of the first material projecting from the bottom of the cavity,
the block formation step is carried so as to obtain, from the part of the first material projecting, a protrusion of second material projecting on said face of the substrate.

According to a first variant, the part of the first material projecting consists of a wall or pillar projecting from the bottom of the cavity.

According to a second variant, the step of forming the cavity is carried out so as to leave several parts of the first material projecting and delimiting several alveoli in the cavity.

The planarizing step can be carried out by chemical-mechanical or mechanical polishing.

According to a particular application, the substrate being made from silicon, a thermal oxidation of the silicon is implemented in order to form a silicon dioxide block.

According to another particular application, the substrate being made from SiGe, a thermal oxidation of the SiGe is implemented in order to form an oxidised SiGe block.

According to yet another particular application, the substrate being made from silicon, a nitriding of the silicon is implemented in order to form an SiN block.

The method can also comprise, between the step of forming the cavity and the step of forming the block, a step of masking the parts of the substrate that are not to undergo said reaction.

After the planarizing step, a step of bonding a thin film on the planarized face of the substrate can be provided.

### BRIEF DESCRIPTION OF THE DRAWINGS

The invention will be better understood and other advantages and particularities will emerge from a reading of the following description given by way of non-limitative example, accompanied by the attached drawings, among which:

FIGS. 1A and 1B, already described, are views in section illustrating a method of producing a mixed substrate according to the prior art,

FIGS. 2A to 2C are views in section illustrating a method of producing a mixed substrate according to the invention,

FIG. 3 is an outline diagram showing the oxidised spacer height as a function of a width of a spacer.

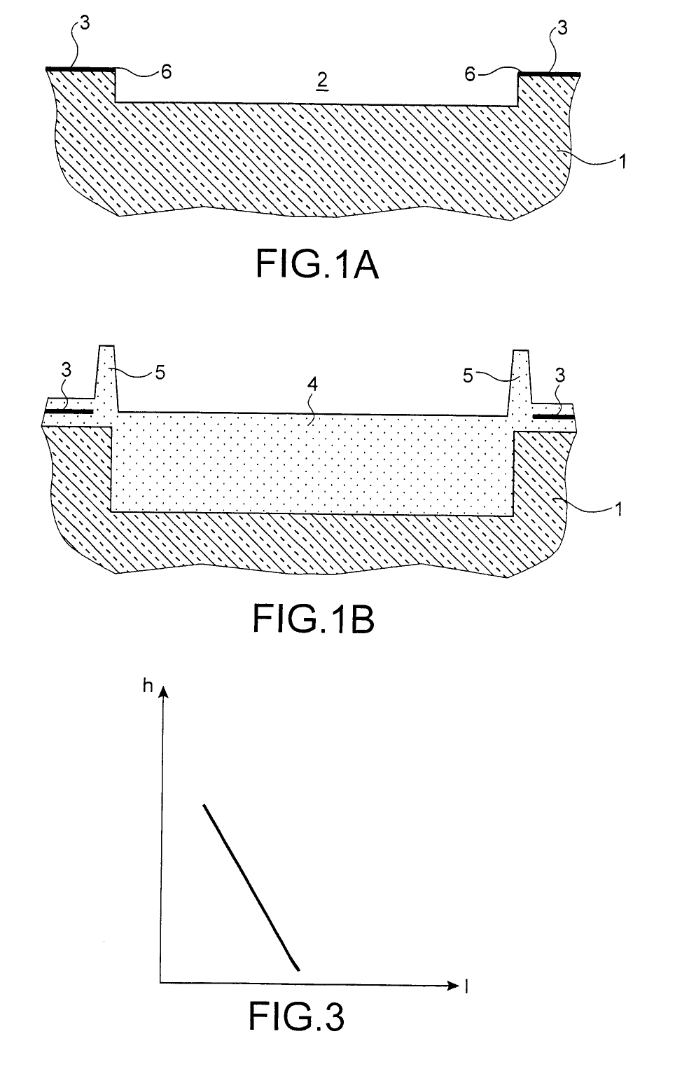

### DETAILED DISCLOSURE OF PARTICULAR EMBODIMENTS

By way of example, in the following the initial substrate will be made from silicon and the block will be made from silicon oxide. The reaction used to obtain the block will be a thermal oxidation of the silicon forming the initial substrate, this oxidation being initiated at the cavity formed in the initial substrate.

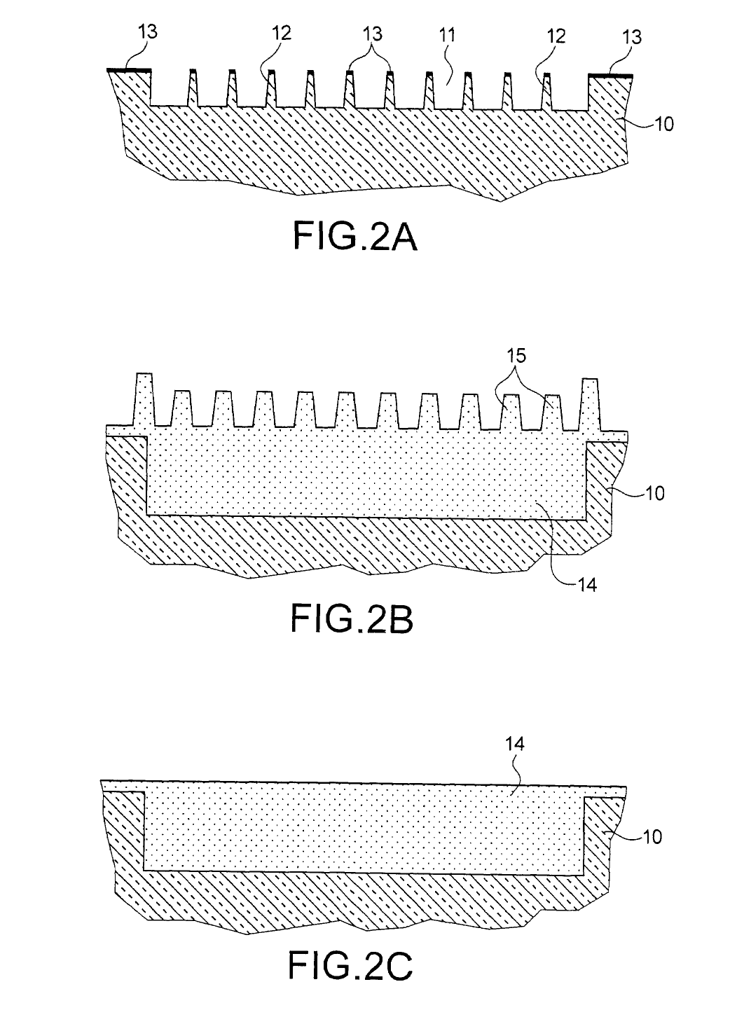

FIGS. 2A to 2C illustrate a method of producing a mixed substrate according to the invention.

FIG. 2A shows a substrate 10 made from silicon on which a layer of silicon nitride 13 has advantageously been deposited on one of its main faces. In a variant, this layer could be deposited after the production of the cavity. From this main face, a cavity has been formed by etching, the layer 13 advantageously being able to serve as an etching mask for producing this cavity. The etching has been carried out so as to leave, in the cavity 11, parts 12 projecting from the bottom of the cavity. The parts 12 are for example pillars or walls. Their number, spacing and size are designed, according to the size of the cavity, so as to prevent or limit the phenomenon of dishing resulting from a subsequent chemical-mechanical planarization. The characteristics of the parts 12 (number, spacing, size) can be assessed during tests.

It will advantageously be sought for the silicon pillars, after thermal oxidation, to be completely oxidised at the cavity 11. The width of these pillars will in particular be correlated with the thickness of oxide that it is wished to generate. The greater this thickness, the wider the pillars can be.

The film 13 of silicon nitride does not cover the cavity 11 and the parts 12 that belong to the cavity. However, it is present on the tops of the parts 12.

The thermal oxidation of the silicon of the cavity is then carried out, that is to say the oxidation of the bottom, the walls of the cavity and the walls of the parts 12 of the cavity. The oxidation is advantageously carried out until the structure shown in FIG. 2B is obtained, which shows a silicon dioxide block 14 formed from the cavity and studded with protrusions 15 also made from silicon dioxide. The oxidation was advantageously carried so as to completely convert the parts 12 (see FIG. 2A) into silicon dioxide. However, according to the application, a little of the silicon parts 12 could remain.

In FIG. 2B, it will be noted that the layer of nitride was completely consumed during the oxidation. In a variant, part of this layer of nitride could remain, surmounted by silicon dioxide.

The following step consists of planarization the main face of the substrate, for example by chemical-mechanical polishing. The polishing eliminates the protrusion 15 and planarizes the main face of the substrate 10. The block 14 has a plane face with minimised dishing, compatible in terms of flatness with the bonding of a thin film for example made from silicon.

### Example Application 1

On the surface of a silicon substrate, a cavity is etched. This cavity, referenced 11 in FIG. 2A, consists of a set of sub-cavities or alveoli separated by parts or partitions or walls (referenced 12 in FIG. 2A) rising from the bottom of the cavity. The cavity has a depth of 1.5 μm. The alveoli have a width of 100 μm. The separation partitions or walls of the alveoli are 2 μm thick.

3 μm of silicon dioxide is produced at the etched area, by thermal oxidation at 1100° C. under steam. The area of the substrate situated outside the future insulating block is protected by a film of silicon nitride in order to prevent its oxidation. It will then be observed that the separation walls of the alveoli are oxidised over a height depending on the initial width of these walls and the thickness of oxide generated. Advantageously, the dimensions of these walls (and in particular the thickness) will be chosen so that the walls are oxidised over their entire initial height. Protrusions 0.8 μm high will also be observed vertically in line with these walls. At the edge of the cavity, the protrusions have a height of between 1 μm and 1.2 μm.

The chemical-mechanical planarization is carried out and characterised in particular vertically in line with the future insulating areas. If the mean value of the dishing obtained on “conventional” areas, that is to say not protected by the protrusions, and on areas “protected” by protrusions, are compact, it can be seen that the dishing is effectively much reduced by virtue of the presence of the protrusions.

For example, during a method of planarizing edge protrusions 1.1 μm high and for adjoining surface insulating areas of 3 mm×3 mm, dishing greater than 50 nm is obtained if the areas do not have any protective protrusions whereas with protrusions the dishing is reduced to less than 50 nm, or even to less than 10 nm. The substrate obtained can then be bonded at this face, after possibly a suitable surface preparation, to a thin film of silicon in order to form a mixed substrate having SOI areas and solid areas.

### Example Application 2

On the surface of a silicon substrate, a cavity is etched. This cavity (referenced 11 in FIG. 2A) consists of a set of sub-cavities or alveoli separated by parts or partitions or walls (referenced 12 in FIG. 2A) rising from the bottom of the cavity. The cavity has a depth of 1.5 μm. The alveoli have a width of 100 μm. The separation partitions or walls of the alveoli are 4 μm thick.

3 μm of silicon dioxide is produced in the etched area, by thermal oxidation at 1100° C. under steam. The area of the substrate situated outside the future insulating block is protected by a film of silicon nitride in order to prevent its oxidation. It will then be observed that the alveoli separation walls are completely oxidised over a height of 0.5 μm. Protrusions 0.7 μm high will also be observed vertically in line with these walls. At the edge of the cavity, the protrusions have a height of between 1 μm and 1.2 μm.

After polishing and surface preparation, this substrate can be assembled with a thin film of silicon oxide oxidised on the surface in order to form an SOI substrate with areas of oxide with different thicknesses.

### Example Application 3

On the surface of a silicon substrate, a cavity is etched. This cavity consists of a set of alveoli separated by walls or spacers rising from the bottom of the cavity. The cavity has a depth of 1.5 μm. The alveoli have a width of 100 μm. The alveoli separation walls are 2 μm thick.

The area situated outside the future insulating block is therefore covered with a film of silicon oxide obtained for example thermally, chemically or by dry method of the plasma or UV/O₃ type, referred to as a pedestal film. The thickness of this film is less than 0.5 μm, preferably less than 50 nm and preferably again less than 20 nm. This film of oxide is protected by a film of silicon nitride intended to form a barrier to subsequent oxidation.

3 μm of silicon oxide is produced in the etched area, by thermal oxidation at 1100° C. under steam. It is then observed that the alveoli separation walls are completely oxidised over a height of 2 μm. Protrusions 0.8 μm high are also observed vertically in line with these walls. At the edge of the cavity, the protrusions have a height of between 1 μm and 1.2 μm.

The chemical-mechanical planarization is carried out and characterised in particular vertically in line with the future insulating areas. If the mean amount of the dishing obtained on “conventional” areas, that is to say not protected by the protrusions, and on areas “protected” by protrusions are compared, it is found that the dishing is actually much reduced by virtue of the presence of the protrusions. It is greater than 50 nm at the “conventional” areas and around 5 nm at “protected” areas.

For example, during a process of edge planarization of protrusions 1.1 μm high and for adjoining surface insulating areas of 3 mm×3 mm, a dishing greater than 50 nm is obtained if the areas do not have protective protrusions while with protrusions the dishing is reduced to less than 5 nm.

This example can be varied with several thickness of oxide, with various forms of projecting parts (spacers, walls, partitions, pillars), with various thickness of spacer, with spacers the width of which varies according to the height (trapezoidal shape), the tops of the projecting parts being able to be wider than their bases (as shown in FIG. 2A) or on the contrary less wide.

The width of the spacers will be smaller, the shorter the oxidation time and therefore the thickness of oxide of the future insulating block.

The width of the spacers will be smaller, the greater the oxidised height of the spacers. The outline diagram of FIG. 3 illustrates this aspect. On this diagram, the Y axis represents the oxidised height h in the spacers and the X axis represents the width 1 of the spacers.

The invention also applies to the thermal oxidation of SiₓGe_{y} or to the nitriding of silicon, but for shallower cavities since nitriding consumes much less silicon than oxidation.

1. Method of producing a mixed substrate, that is to say a substrate comprising at least one block of material different from the material of the substrate, the method comprising the following successive steps:
formation of a cavity (11) in a substrate of first material (10), and from one of its faces,
formation of the block (14) by means of a reaction, initiated from the walls of the cavity (11), between the first material and at least one chemical element contributed in order to obtain a second material filling the cavity (11),
planarizing said first face of the substrate, characterised in that:
the step of forming the cavity (11) is carried out so as to leave at least part of the first material (12) projecting from the bottom of the cavity,
the block formation step is carried out so as to obtain, from the part of the first material (12) projecting, a protrusion of second material (15) projecting on said face of the substrate (10).

2. Method according to claim 1, in which the part of the first material (12) projecting is formed by a wall or a pillar projecting from the bottom of the cavity.

3. Method according to claim 1, in which the step of forming the cavity is carried out so as to leave several parts of the first material projecting and delimiting several alveoli in the cavity.

4. Method according to claim 1, in which the planarizing step is carried out by chemical-mechanical or mechanical polishing.

5. Method according to any one of claims 1 to 4, in which, the substrate (10) being made from silicon, a thermal oxidation of the silicon is implemented in order to form a block of silicon oxide (14).

6. Method according to any one of claims 1 to 4, in which, the substrate being made from SiGe, a thermal oxidation of the SiGe is implemented in order to form a block of oxidised SiGe.

7. Method according to any one of claims 1 to 4, in which, the substrate being made from silicon, a nitriding of the silicon is implemented in order to form a block of SiN.

8. Method according to any one of claims 1 to 7, comprising, between the step of forming the cavity and the step of forming the block, a step of masking parts of the substrate that are not to undergo said reaction.

9. Method according to any one of claims 1 to 8, in which, after the planarizing step, a step of bonding a thin film on the planarized face of the substrate is provided.
